(19) United States
(12) Patent Application Publication
(10) Pub. No.: US 2007/0081403 A1
(43) Pub. Date: Apr. 12, 2007

(54) Semiconductor memory device

(76) Inventor: Yasuhiro Nanba, Tokyo (JP)

Correspondence Address: YOUNG & THOMPSON, 745 SOUTH 23RD STREET, 2ND FLOOR, ARLINGTON, VA, 22202, US

(21) Appl. No.: 11/246,223

(22) Filed: Oct. 11, 2005

(51) Int. Cl. G11C 29/00

(52) U.S. Cl. 365/201

(57) ABSTRACT

A second roll call test mode is added in addition to a first roll call test mode for checking use/nonuse of a redundancy circuit. A semiconductor memory device is capable of confirming program states of an enable fuse and each address fuse by providing with a logic circuit which blocks program information of the enable fuse by using a second test mode signal.

This application claims priority to prior application JP 2004-295191, the disclosure of which is incorporated herein by reference.

### BACKGROUND OF THE INVENTION

1. Field of the Invention

The present invention relates to a semiconductor memory device, and in particular, to a semiconductor memory device comprising a redundancy circuit having a fuse storing relief information.

2. Description of the Related Art

Semiconductor memory devices have been advancing and have become increasingly used on a large scale each year. For example, in DRAMs, 1 G-bit memories are being developed adopting a design rule of 0.1 microns or less. Used on a large scale, a redundancy circuit technique is adopted for reliefing from a failure by arranging a redundancy cell array for a memory cell array and by replacing a failed memory cell with a redundancy cell.

As a conventional example, a block diagram of the entire structure of a semiconductor memory device using a DDR (Double Data Rate) technique is shown in FIG. 1. Here, for simplicity, a single redundancy circuit is provided for the entire memory cell array of a semiconductor device, however, it is also possible to provide a redundancy circuit for each unit (bank, array block).

A semiconductor memory device comprises a row redundancy decoder 16, a column redundancy decoder 17, a test mode entry block 6, a row call circuit 18, a command decoder 1, a control circuit 2, and a mode register 3. The semiconductor memory device also comprises a clock generator 4, a DLL circuit 5, a row address buffer and refresh counter 7, a column address buffer and burst counter 8, a data control logic circuit 12, and a column decoder 10. The semiconductor memory device further comprises a sense amplifier 11, a row decoder 9, a row redundancy cell array 19, a column redundancy cell array 20, a memory cell array 90, a latch circuit 13, a data output buffer 14, and a data input buffer 15.

An address is supplied to the test mode entry block 6, the command decoder 1, the mode register 3, the row address buffer and refresh counter 7, and the column address buffer and burst counter 8. The clock generator 4 receives clock signals CK, /CK and a clock enable CKE, generates an internal clock signal 105 and supplies the internal clock signal 105 to every part of the semiconductor memory device.

The DLL circuit 5 receives the clock signals CK, /CK and outputs a synchronizing signal 106 to the latch circuit 13, the data output buffer 14 and the data input buffer 15. The command decoder 1 receives a chip select signal /CS, a row address strobe signal /RAS, a column address strobe signal /CAS, a write enable signal /WE and the address and outputs the decode result 101 to the control circuit 2.

The mode register 3 receives the address and outputs an operation mode set signal 102 to the control circuit 2.

The control circuit 2 generates a control signal 104 in response to the internal clock signal 105 from the clock generator 4 on the basis of the output 101 of the command decoder 1 and the output 102 of the mode register 3. The control signal 104 is supplied to the test mode entry block 6, the row address buffer and refresh counter 7, the column address buffer and burst counter 8, the sense amplifier 11, the row decoder 9, and the latch circuit 13. Thus, the operations of the corresponding parts inside the semiconductor memory device are controlled.

The control signal 104 supplied to a redundancy control block 80 comprising the row redundancy decoder 16, the column redundancy decoder 17 and the roll call circuit 18 is a precharge (PRE) signal and fuse control signals (FPV, FCT, FTG) (See FIGS. 2 and 3).

The operations when data are read/written without using the redundancy circuit are well known, and therefore, they are explained in a simple manner. The addresses are held in the row address buffer 7 and the column address buffer 8, and the row decoder 9 and the column decoder 11 specify the address of the memory cell array 90 on the basis of held addresses 107 and 108, respectively.

When reading, the data read out from the memory cell array 90 are sensed by the sense amplifier 11, and sense information 109 is input into the data control logic circuit 12 and output as a data signal 110. The data signal 110 is input into the latch circuit 13 and output as a data signal 111. Data are output from the data output buffer 14 into which the data signal 111 is input through an outer I/O pin.

When writing, the data which are input into the data input buffer 15 from the outer I/O pin are supplied to the sense amplifier 11 via the latch circuit 13 and the data control logic circuit 12, oppositely to a case for reading. The data are sensed by the sense amplifier 11 and written into a designated address in the memory cell array 90.

Next, a conventional redundancy control, which is relevant to the present invention, is described referring to FIGS. 1-4. FIG. 1 is a block diagram showing the entire structure of a semiconductor memory device. FIG. 2 is a redundancy control block diagram incorporating a capacitor fuse. FIG. 3 is a schematic diagram of a fuse circuit, and FIG. 4 is a state diagram of a fuse circuit part.

When redundancy determining signals 112 and 113 (row side 112, column side 113) are selected, a word line and a Y-switch of a decoder circuit (a row decoder 9 for a row side 112, a column decoder 10 for a column side 113) corresponding to the addresses are stopped, and a normal access to a memory cell inside a memory cell array 90 is ceased. At the same time, the row side 112 selects a redundancy word line, the column side 113 selects a redundancy Y-switch, and the corresponding redundancy cell (a row redundancy 19 for the row side 112, a column redundancy 20 for the column side 113) is accessed. Thus, a failed cell is relieved.

Next, the circuit operations of the row redundancy decoder 16 and the column redundancy decoder 17, which generate redundancy determining signals 112 and 113, are described. By setting the PRE signal 104 to ‘Low’, a P-ch transistor 21 turns on, and the redundancy determining signals 112 and 113 are precharged to ‘High’. Then, the PRE signal 104 is set to ‘High’, the P-ch transistor 21 turns off, and a signal line 116 is maintained at a GND level via an inverter 22. The number of transistor columns such as N-ch transistors 23 and 25 is the same as the total number of enable fuses and redundancy addresses to be activated when using redundancy.

Only when being equal to the redundancy addresses, the levels of the signals 118 and 121, etc. input into the gates of the N-ch transistors 23 and 25, etc. are maintained at the GND level. Accordingly, the redundancy determining signals 112 and 113 become disconnected from the GND level of the signal line 116, and only in such a case, the signals are kept at a high level. When the redundancy and the enable fuse are unused and at least one of redundancy addresses is different, the levels of the redundancy determining signal 112 and 113 are lowered to the GND level of the signal line 116 via any of the N-ch transistors 23 and 25, etc.

Here, the fuse circuits 36 and 37, etc. are described referring to FIG. 3. A capacitor fuse is given as an example of a fuse circuit. When programming a capacitor fuse 41, an electric field is applied to both terminals of the capacitor, both the terminals are short-circuited, and the fuse is operated as a resistor when in a connected state. When connected, the fuse is a resistor, and when not connected, the fuse is a capacitor. In the circuit example, a circuit for applying a high electric field is omitted at the time of programming.

For determining such a connected state, one end 127 of the capacitor fuse 41 is connected to GND, and a potential is applied to another end 126. When the fuse in a connected state, the potential is drawn out and when in an unconnected state, the potential is kept and the determination is performed. To be more specific, one side 127 of the capacitor fuse 41 is connected to GND and a fuse control signal 104 is activated. An FPV signal 122 is at a high level, an FTG signal 123 and an FCT signal 124 are at a low level, N-ch transistors 38 and 40 are on, and N-ch transistors 42, 43 and 45 are off.

The terminal 126 of the capacitor fuse 41 is charged to HVCC (assuming a level for applying to a memory cell at a ½ VCC level). Then, the FPV signal 122 is at a low level, and it is determined whether the HVCC level for applying to the terminal 126 is kept as it is or drawn out to the GND level of the terminal 127 according the state of the capacitor fuse 41.

After sufficient time passes, the FTG signal 123 is at a high level, the level of the terminal 126 of the capacitor fuse 41 is transmitted to a differential amplifier 44 and a latch circuit 46, and finally, the latch circuit 46 latches fuse connect information. The fuse determining signals 117 and 119, etc. are in a high state when in a connected state and in a low state when in an unconnected state according to the connected state of each of the capacitor fuses.

In the redundancy decoders 16 and 17, by the output 118 of an enable fuse determining signal 117 and the output 121 of a comparing circuit 70 which compares the address fuse determining signal 119 and address information, the redundancy determining signals 112 and 113 are activated or inactivated.

FIGS. 4A and 4B show tables for summarizing the states of internal contacts. FIG. 4A is a state table for enabling fuses, and FIG. 4B is a state table for address fuses. As for a logic of an enable fuse, the information of a determining signal 117 of the enable fuse is simply used, and at the time of the fuse being used (connect), the signal 118 input into the gate of an N-ch transistor 23 is in a low state, and GND drawing out of the redundancy determining signals 112 and 113 is stopped.

Next, as for a logic of an address fuse shown in FIG. 4B, a fuse determining level and an address signal are simply compared. In this description, an exclusive OR logic is adopted. Assume in a fuse circuit 37, a high level is programmed in an address A0. In such a case, a fuse determining signal 119 is at a high level. Thus, since an N-ch transistor 32 is on, and a signal line 120 is at a low level via an inverter 30, a P-ch transistor 26 is on, and transfer gates 28 and 29 are off.

Here, when A0 is ‘High’, an A0T signal is ‘High’, and an N-ch transistor 31 is on, and accordingly, a signal line 121 is in a low state, and an N-ch transistor 25 is off. Thus, the redundancy determining signals 112 and 113 are not drawn out to a GND level of a signal line 116.

Next, assume in the fuse circuit 37, a low level is programmed in an address A0. In such a case, the fuse determining signal 119 is at a low level. Thus, since the N-ch transistor 32 is off, and the signal line 120 is at a high level via the inverter 30, the P-ch transistor 26 is off, and the transfer gates 28 and 29 are on.

Here, when A0 is ‘Low’, the A0T signal is ‘Low’, and the transfer gates 28 and 29 are on, and accordingly, the signal line 121 is in a low state, and the N-ch transistor 25 is off. Thus, the redundancy determining signals 112 and 113 are not drawn out to the GND level of the signal line 116. When the fuse determining signal 119 and A0 are opposite, the results are also opposite. As shown in FIG. 4B, the N-ch transistor 121 is on, and the redundancy determining signals 112 and 113 are drawn out to the GDN level of the signal line 116.

That is, if an address is ‘High’ at the time of a fuse being used (connect), and the address is ‘Low’ at the time of a fuse not being used (unconnect), GDN drawing out of the redundancy determining signals 112 and 113 is stopped. Only when the information 119 programmed in a fuse and an outer address are identical, the redundancy determining signals 112 and 113 are ‘High’.

Next, a roll call test is described as one of test modes. A roll call test mode is used for circuit evaluations, selection time reduction, etc on a manufacturer side by an input address at timing when a user does not perform a mis-entry. When entering into the roll call test mode, the use state of redundancy is proved by ‘High’ data output from an output pin if the input address is used for redundancy.

In a roll call circuit 18, when a test mode signal 103 TMODE1 for a roll call is output at a high level from a test mode entry circuit 6, a signal line 137 is ‘Low’ via an inverter 33. When the address is used for redundancy, the redundancy determining signals 112 and 113 are ‘High’, and a signal line 115 is ‘Low’ via an inverter 34. A signal line 114 is ‘High’ by two signals using an NOR circuit 35. The data are directly output from a data output buffer 14 into an I/O pin. When the address is not used for redundancy, ‘Low’ data are output.

The above descriptions are specifications for a redundancy and for a roll call test mode according to a conventional technique.

For a redundancy circuit, many prior arts are disclosed. In Patent Document 1 (Japanese Unexamined Patent Application Publication No. 2000-123593), a technique is disclosed which comprises a laser fuse for carrying out the relief in a wafer state and an electric fuse for carrying out the relief after assembling and improves the relief efficiency by using two kinds of redundancy circuits. In Patent Document 2 (Japanese Unexamined Patent Application Publication No. 2004-164737), a technique is disclosed regarding a circuit for relieving a failed memory cell and a circuit for relieving an operation timing failure.

In Patent Document 3 (Japanese Unexamined Patent Application Publication No. 2004-178674), a semiconductor device is disclosed which comprises a comparing circuit inside a memory circuit for relieving with a low-cost tester. Japanese Unexamined Patent Application Publication No. 2004-296051 filed by the applicant discloses a method for reading out information stored in a fuse of a redundancy circuit.

As described above, recently, semiconductor devices have been used on a large scale, the numbers of redundancy circuits and of used fuses have been increasing, and accordingly, it has been strongly desired to confirm whether or not the fuses are in a right state. For example, in FIG. 2, when an enable fuse is set to be in a connected state but is not rightly set, coming to be in an unconnected state, since redundancy determining signals 112 and 113 are drawn out to a GND level of a signal line 116 via an N-ch transistor 23, connect information of other address fuses is not known, and accordingly, whether or not programming is rightly performed cannot be determined.

### SUMMARY OF THE INVENTION

The present invention is to provide a semiconductor memory device capable of easily confirming whether or not a fuse is set in a right state, taking the above-mentioned problems into consideration.

The present invention is applied to a semiconductor memory device provided with a redundancy circuit comprising fuses.

According to an aspect of the present invention, the semiconductor memory device has a first roll call test mode and a second roll call test mode. Program information of the fuses is separately read out in the first and second roll call test modes.

In the semiconductor memory device, it is preferable that the semiconductor memory device further comprises a logic circuit which determines a logic output level by using a test mode signal in the second roll call test mode regardless of program information of an enable fuse included in the fuses.

It is preferable that the logic circuit is a two-input NOR circuit using as inputs the test mode signal and the program information of the enable fuse.

It is preferable that the semiconductor memory device further comprises a transistor whose gate is connected to the output of the two-input NOR circuit, whose drain is connected to a redundancy determining signal, and whose source is connected to a ground potential.

It is preferable that the fuse is a capacitor fuse.

In the semiconductor memory device, the logic circuit may be a two-input NOR circuit using as inputs the test mode signal and a reverse signal of an enabling signal. In this case, it is preferable that the semiconductor memory device comprises the fuse whose one end is connected to a redundancy determining signal, and a transistor whose drain is connected to another end of the fuse, whose source is connected to a ground potential, and whose gate is connected to the output of the two-input NOR circuit. Further, it is preferable that fuse is a laser fuse.

By structuring in such a manner according to the present invention, program information of an enable fuse and of each address fuse can be obtained without a circuit change in large scale.

### BRIEF DESCRIPTION OF THE DRAWINGS

FIG. 1 is a configuration block diagram of a conventional semiconductor memory device;

FIG. 2 is a redundancy control block diagram of a conventional semiconductor memory device;

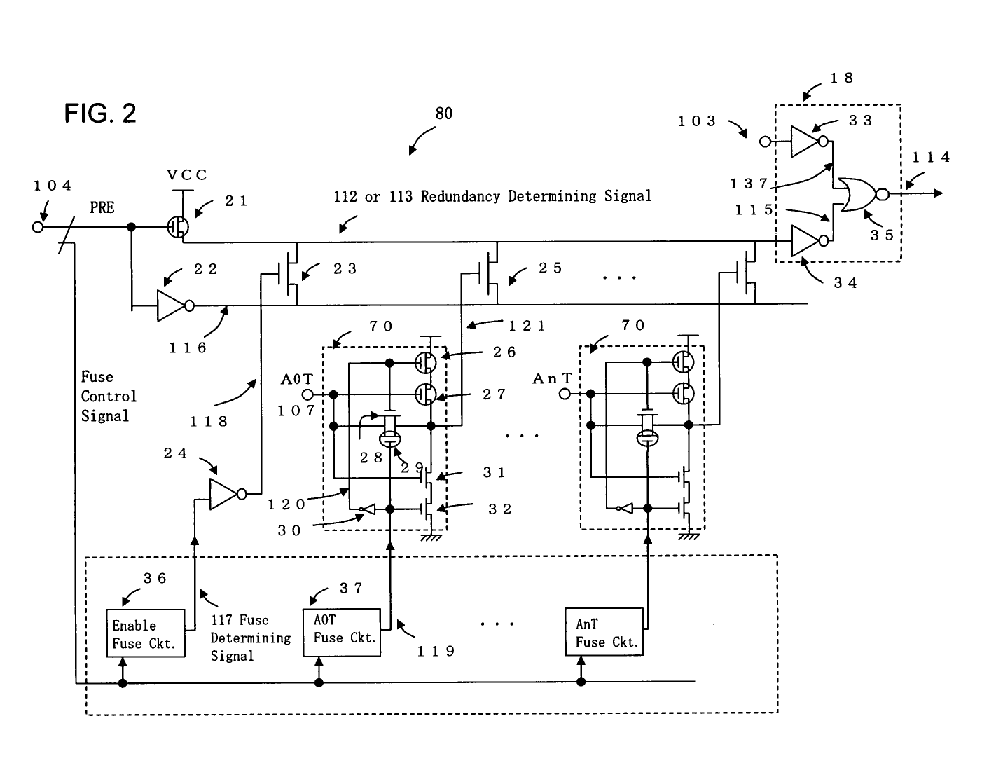

FIG. 3 is a fuse circuit diagram of a conventional semiconductor memory device;

FIGS. 4A and 4B show state tables of a conventional semiconductor memory device, where FIG. 4A is a state table for enable fuses, and FIG. 4B is a state table for address fuses;

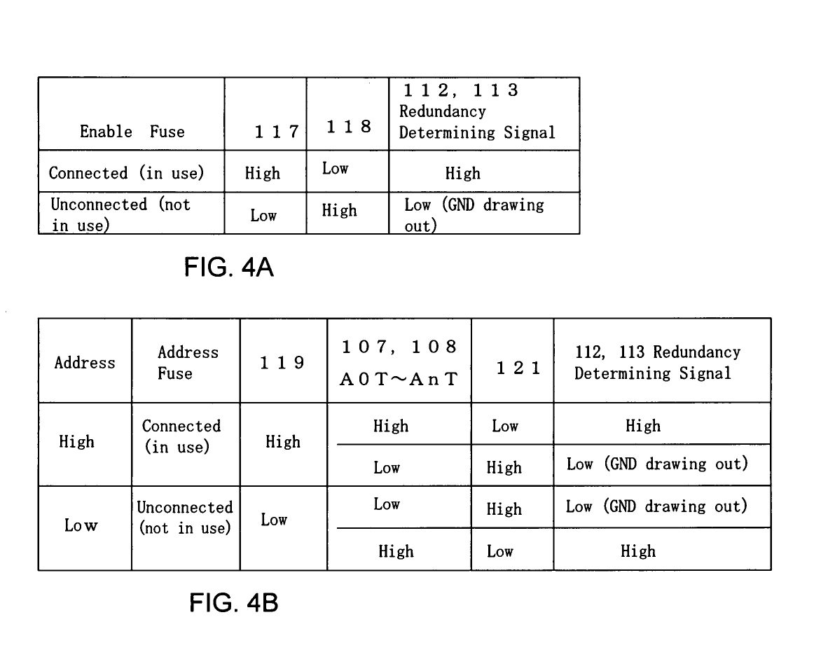

FIG. 5 is a configuration block diagram of a semiconductor memory device according to the present invention;

FIG. 6 is a redundancy control block diagram of a semiconductor memory device according to a first embodiment of the present invention; and

FIG. 7 is a redundancy control block diagram of a semiconductor memory device according to a second embodiment of the present invention.

### DESCRIPTION OF THE PREFERRED EMBODIMENTS

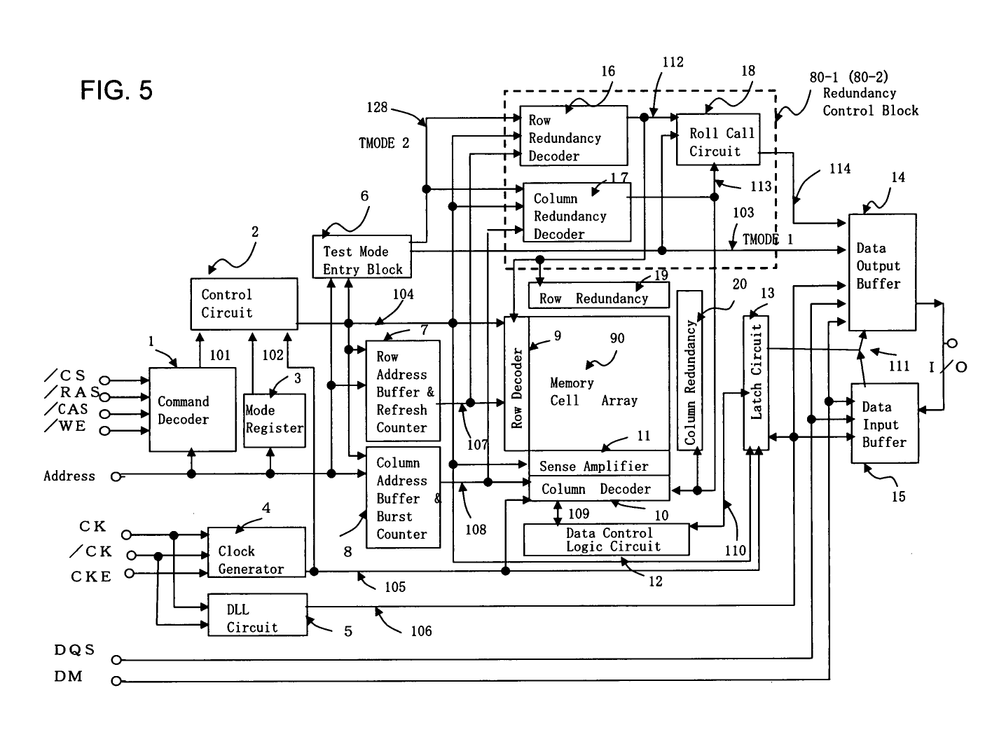

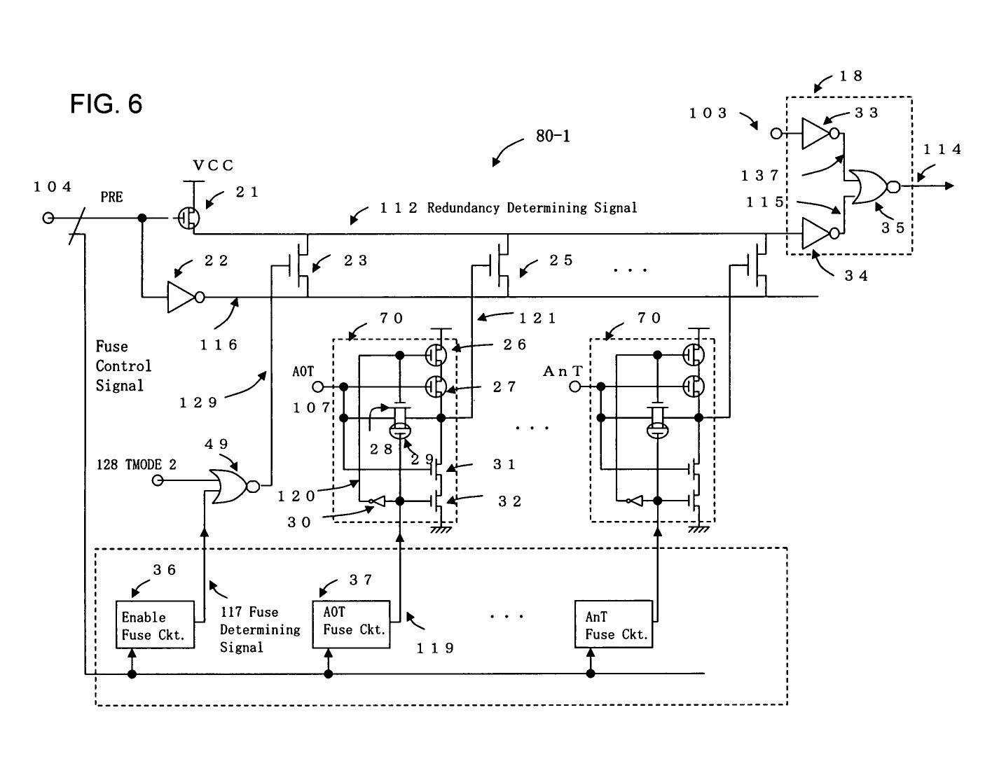

A first embodiment of the present invention is described referring to FIGS. 5 and 6. FIG. 5 is a block diagram showing the entire structure of a semiconductor memory device; and FIG. 6 is a redundancy control block 80-1 showing the use of a capacitor fuse. Here, for simplicity, a single redundancy circuit is formed for the entire memory cell array of a semiconductor memory device, however, it is also possible to form a redundancy circuit for each unit (bank, array block).

In the present invention, a program check mode of a fuse is further added to a conventional semiconductor memory device as a second roll call test mode. A function is added to a test mode entry block 6 such that TMODE2 is added as a second test mode signal 128 and supplied to a row redundancy decoder 16 and a column redundancy decoder 17.

A semiconductor memory device shown in FIG. 5 comprises a row redundancy decoder 16, a column redundancy decoder 17, a test mode entry block 6, a row call circuit 18, a command decoder 1, a control circuit 2, and a mode register 3. The semiconductor memory device also comprises a clock generator 4, a DLL circuit 5, a row address buffer and refresh counter 7, a column address buffer and burst counter 8, a data control logic circuit 12, a column decoder 10, and a sense amplifier 11. The semiconductor memory device further comprises a row decoder 9, a row redundancy cell array 19, a column redundancy cell array 20, a memory cell array 90, a latch circuit 13, a data output buffer 14, and a data input buffer 15.

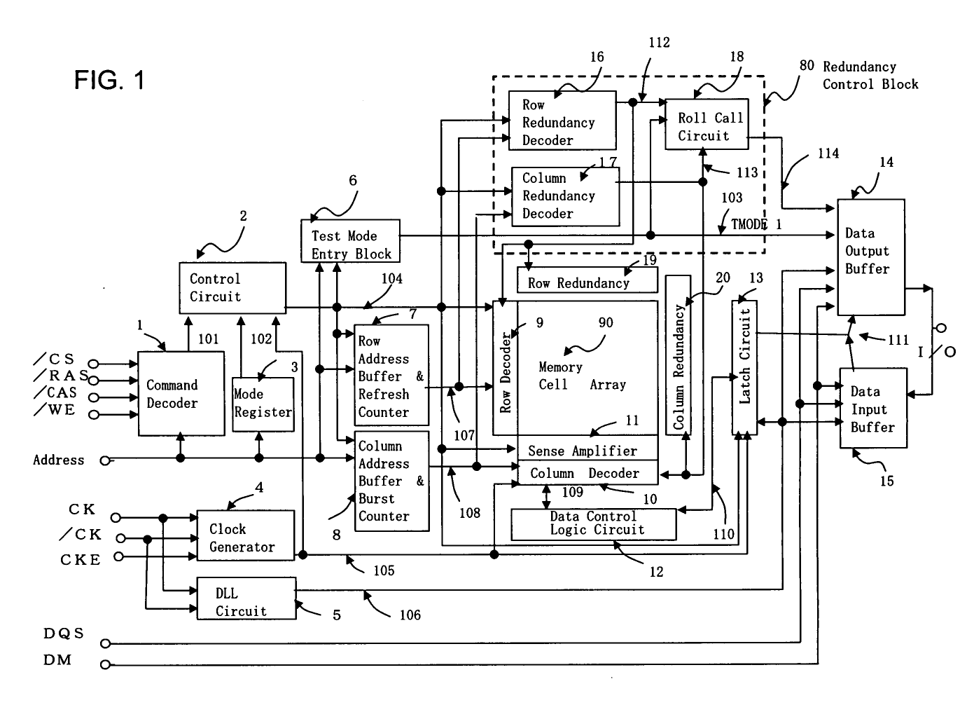

The semiconductor memory device according to the embodiment is to generate a second test mode signal 128 in addition to a roll call test mode signal 103 in a test mode entry block 6 of a conventional semiconductor memory device (FIG. 1). The generated second test mode signal 128 is supplied to the row redundancy decoder 16 and the column redundancy decoder 17. Other structures and operations are the same as those of a conventional semiconductor memory device, and thereby, detailed description is omitted. The program check mode of a fuse as the second roll call test mode according to the embodiment is described below.

In the second roll call test mode, whether or not programming is performed to a fuse of a redundancy circuit is checked, and the result of checking is output to an output terminal similarly as the roll call test. Both the test mode signal (TMODE1) 103 and the second test mode signal (TMODE2) 128 are activated (set at a high level), coming into the second roll call test mode. In such a state, it is determined whether or not programming is performed to the fuse.

The test mode signal (TMODE1) 103 is input into the roll call circuit 18 and the output buffer 14. The roll call circuit 18 transfers a redundancy determining signal to the data output buffer 14 by setting the test mode signal (TMODE1) 103 at a high level. The data output buffer switches a data output bus from a memory cell and outputs the output from the roll call circuit 18 as data. The second test mode signal (TMODE2) 128 is input into the row redundancy decoder 16 and the column redundancy decoder 17, and the programming state of a fuse is output.

Detailed description is given below referring to FIG. 6. Here, for simplicity, only redundancies on the row side are described, but it is apparent that the redundancies on the column side are similar.

A fuse circuit includes an enable fuse circuit 36 which indicates use/nonuse of a redundancy circuit, and a plurality of address fuse circuits 37 which indicate each of the addresses, and the fuse circuit outputs fuse determining signals 117 and 119 respectively.

The enable fuse determining signal 117 is input into an NOR circuit (two input NOR circuit) 49, and the output of the NOR circuit is input into the gate of an N-ch transistor 23. A second test mode signal (TMODE2) 128 is input into another input of the NOR circuit 49.

Each address fuse determining signal 119 is input into each address comparing circuit 70 and compared with an address input 107. As a result of comparison, when being identical, a low level is output into the gate of an N-ch transistor 25 and when not being identical, a high level is output thereinto.

The sources of the N-ch transistors 23 and 25 are commonly connected to the output of an inverter 22, and the drains are commonly connected to that of a P-ch transistor 21 to generate a redundancy determining signal 112 for determining use/nonuse of a redundancy circuit. The source of the P-ch transistor 21 is connected to a power source voltage Vcc, and a precharge signal PRE of a control signal 104 is input into the gate of the P-ch transistor 21. The precharge signal PRE is similarly input into the inverter 22.

In the roll call circuit 18, the redundancy determining signal 112 is input into an inverter 34 and the output thereof is input into an NOR circuit 35. Through an inverter 33, a reversed phase signal of the test mode signal 103 is input into another input of the NOR circuit 35, and the output 114 of the NOR circuit 35 is input into the data output buffer 14 (FIG. 5).

In such a structure, the operations of a program check mode of a fuse is described. Both the test mode signals TMODE1 and TMODE2 are set to be at a high level.

A PRE signal of the fuse control signal is set to be at a low level, and thereby, the P-ch transistor 21 is turned on, the redundancy determining signal 112 is at a high level, the PRE signal is reversed by the inverter 22, and the signal line 116 is at a high level. Then, by changing the PRE signal to a high level, the redundancy determining signal 112 is at a high level, and the signal line 116 is at a low level.

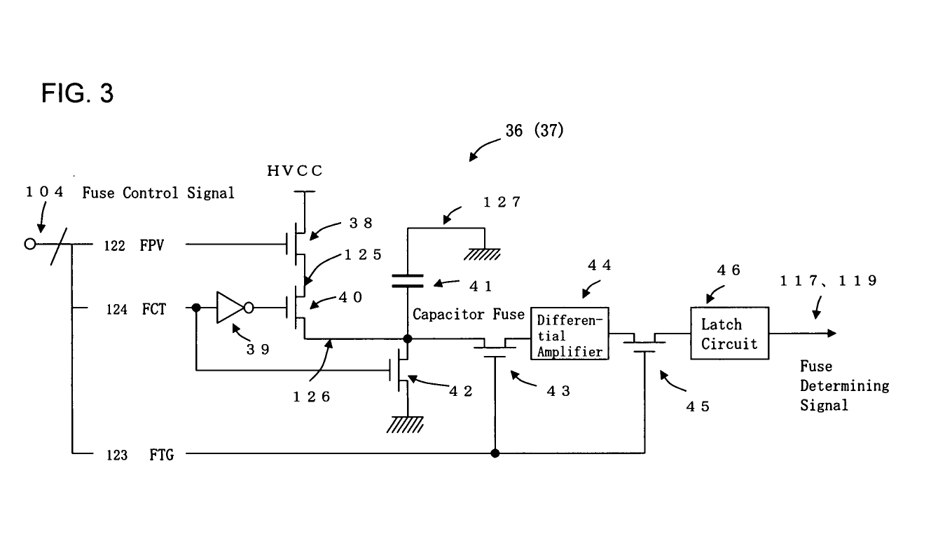

The operations of the fuse circuit are also described referring back to FIG. 3. Fuse control signals (FPV, FTG and FCT) are input into the fuse circuit. An FPV signal 122 is at a high level, an FTG signal 123 and an FCT signal 124 are at a low level, N-ch transistors 38 and 40 are turned on, and N-ch transistors 42, 43 and 45 are turned off. A terminal 126 of the capacitor fuse 41 is charged to HVCC (assuming a level for applying to a memory cell at a ½ VCC level).

Then, the FPV signal 122 is at a low level, and it is determined whether the HVCC level applied to the terminal 126 is kept as it is or drawn out to the GND according the program state of the capacitor fuse 41. After sufficient time passes, the FTG signal 123 is at a high level, the level of the terminal 126 of the capacitor fuse 41 is transmitted to a differential amplifier 44 and a latch circuit 46, and finally, the latch circuit 46 latches fuse connect information.

According to the program state of each of the capacitor fuses, the fuse determining signals 117 and 119 are output at a high level when the capacitor fuse is connected and at a low level when the capacitor fuse is unconnected.

Turning back to FIG. 6, though the enable fuse determining signal 117 is input into the NOR circuit 49, the output of the NOR circuit 49 is at a low level regardless of the level of the fuse determining signal 117 indicating whether or not being programmed into an enable fuse since the second test mode signal TMODE2 input into one terminal of the NOR circuit 49 is at a high level. Accordingly, the N-ch transistor 23 is off, and the redundancy determining signal 112 is kept at a high level regardless of being programmed into the enable fuse.

The address fuse determining signal 119 is input into the address comparing circuit 70, and is determined to be identical or not identical with an address signal 107 to be input. The address fuse is programmed when an address is at a high level, and the fuse determining signal is output at a high level. When the address is at a low level, the fuse determining signal 119 is output at a low level. When the fuse determining signal 119 and the input address 107 are identical, a low level is output from the address comparing circuit 70. When they are not identical, a high level is output therefrom.

According to the level of the signal 121 from the address comparing circuit 70, the on/off state of an N-ch transistor 25 is controlled. When the input address 107 and the program contents of a fuse are identical, a low level is input, the N-ch transistor 25 is turned off, and the redundancy determining signal 112 is kept at a high level. When the input address 107 and the program contents of the fuse are not identical, the N-ch transistor 25 is turned on, and the redundancy determining signal 112 is changed to be at a low level.

The redundancy determining signal 112 is output from a data output buffer 14 via the roll call circuit 18. When the redundancy determining signal is at a high level, it can be determined that An is identical from the address programmed in the address fuse and the input address AO. When the redundancy determining signal is at a low level, it can be determined that the address programmed in the address fuse and the input address are not identical.

Here, for example, an address which is automatically generated from the row address buffer and refresh counter 7 is repeatedly input, and the redundancy determining signal 112 searches an address for being at a high level. By automatically generating the address, the fuse address programmed in the fuse can be read out. By determining whether or not the read out fuse addresses A0-An are in the corresponding address state, it can be determined whether or not programming into the corresponding separate fuse is rightly performed.

An enabling fuse program state can be determined by performing a roll call test by using the read out fuse address as an address input and by keeping a second test mode signal TMODE2 at a low level.

In the prior art, when the enable fuse is mis-programmed, the program state of the address fuse was not determined since the output of the enable fuse circuit 36 is at a low level and the redundancy determining signal is at a low level.

In the present invention, the corresponding fuse connect information can be obtained without a circuit change in large scale at all.

In the embodiment, by additionally inputting the test mode signal TMODE2 as a second roll call test mode, the determining signal from an enable fuse is blocked, and the program state of the corresponding address fuse is made checkable. By combining with a first test mode signal, the program state of the enable fuse can be checked. By combining in such a manner, a semiconductor memory device can be obtained capable of easily confirming whether or not each fuse is set in a right state.

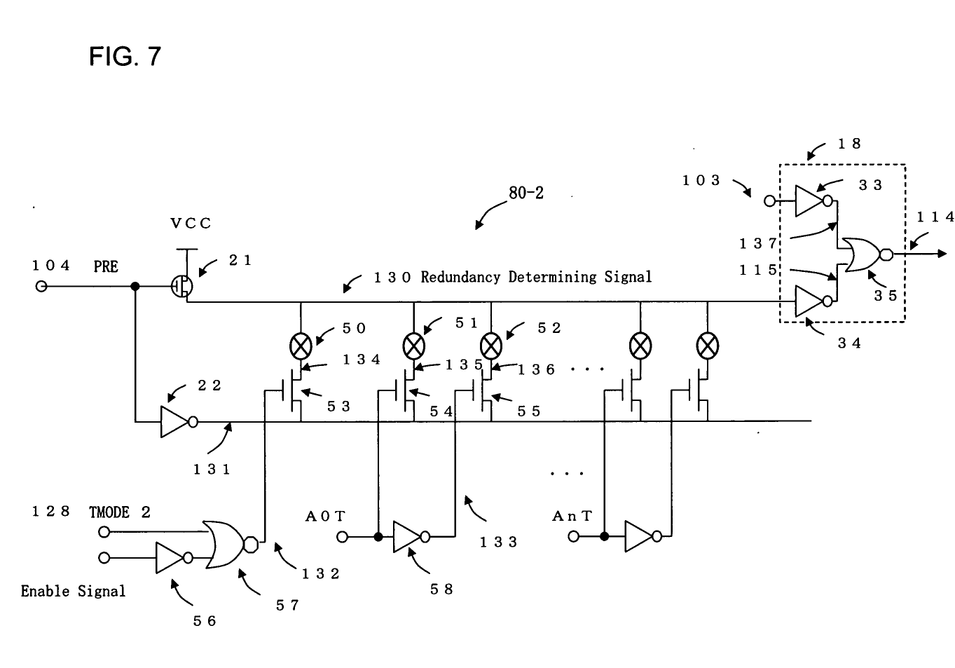

A redundancy control block 80-2 according to a second embodiment of the present invention is shown in FIG. 7. The second embodiment is for a case when a laser fuse is used for the fuse part instead of using a capacitor fuse. A laser fuse is a fuse which is programmed by irradiating laser at a wafer stage for cutting thereof. Thus, oppositely to a capacitor fuse, when not being programmed, the fuse is a resistor and in a connected state, which would be open and in an unconnected state after being programmed.

Referring to FIG. 7, for simplicity, only redundancies on the row side are described, but it is apparent that the redundancies on the column side are similar.

The fuse includes an enable fuse 50 indicating use/nonuse of a redundancy circuit, and address fuses 51, 52, etc. indicating the corresponding addresses and reversed addresses. Both terminals of each of the fuses are connected to a redundancy determining signal 130 and the drains of N-ch transistors 53, 54 and 55. The sources of N-ch transistors 53, 54 and 55 are connected to a signal line 131. The gate of the N-ch transistor 53 is connected to a signal line 132 for an enable signal and a second test mode signal. That is, the enable signal is inverted by an inverter 56 and input into one of terminals of a two-input NOR circuit 57 as a reversed signal. The second test mode signal (TMODE2) 128 is input into another one of terminals of the NOR circuit 57. An address signal A0T is input into the gate of the N-ch transistor 54. The address signal A0T is inverted by an inverter 58 and input into the gate of the N-ch transistor 55 as a reversed signal 133.

The source of the P-ch transistor 21 is connected to a power source voltage Vcc, and a precharge signal PRE of the control signal 104 is input into the gate of the P-ch transistor 21. The precharge signal PRE is also input into the inverter 22. The redundancy determining signal 130 is input into an inverter 34 and the output thereof is input into an NOR circuit 35. A reversed signal of the test mode signal 103 is input into another input of the NOR circuit 35, and the output of the NOR circuit 35 is input into the data output buffer 14 (FIG. 5).

In such a structure, the operations of a program check mode of a fuse is described. Both the test mode signals TMODE1 and TMODE2 are set to be at a high level.

First, a PRE signal is set to be at a low level, and thereby, the P-ch transistor 21 is turned on, the redundancy determining signal 130 is at a high level, the PRE signal is inverted by the inverter 22, and the signal line 131 is at a high level. Then, by changing the precharge signal PRE to be at a high level, the redundancy determining signal 130 is at a high level, and the signal line 131 is at a low level.

When a laser fuse 50 for an enable signal is cut, the redundancy determining signal 130 is not drawn down to the GND level of the signal line 131 regardless of High/Low of the enable signal. When the laser fuse 50 for the enable signal is not cut, the signal line 132 is at a high level with the enable signal being High, the N-ch transistor 53 is turned on, and a redundancy determining signal 130 is drawn down to the GND level of the signal line 131.

When a second test mode signal TMODE2 is at a high level, the output of an NOR circuit 57 is at a low level, an N-ch transistor 53 is turned off, the redundancy determining signal 130 is kept at a high level regardless of a laser fuse 50 being in a cut state, and the signal is not drawn down to the GND level.

The address fuse includes two fuses corresponding to a normal phase signal and a reversed phase signal of an address, one of which is cut and the other of which is not cut. Only when fuse cut information and the address are identical, the redundancy determining signal 130 maintains High information.

For example, when the address fuse 51 is laser-cut, the address fuse 52 is not cut and a high level is input as and address A0T, an N-ch transistor 54 is turned on, an N-ch transistor 55 is turned off, and a redundancy determining signal 130 is kept at a high level. When a low level is input as the address A0T, the N-ch transistor 54 is turned off, the N-ch transistor 55 is turned on, and the redundancy determining signal 130 is drawn down to a low level.

Here, for example, an address which is automatically generated from the row address buffer and refresh counter 7 is repeatedly input, and the redundancy determining signal 130 searches an address for being at a high level. By automatically generating the address, the fuse address programmed in the fuse can be read out. It can be determined whether or not the read out fuse addresses A0-An are in the corresponding set address state, and whether or not programming into the corresponding fuse is rightly performed.

An enabling fuse program state can be determined by performing a roll call test by using the read out fuse address as an address input and by keeping a second test mode signal TMODE2 at a low level.

In the prior art, when the enable fuse is mis-programmed, the redundancy determining signal is at a low level and accordingly, the program state of the address fuse cannot be determined. In the embodiment, the corresponding fuse connect information can be obtained without a circuit change in large scale at all.

In the embodiment, a test mode signal TMODE2 is added and input as a second roll call test mode. By the test mode signal TMODE2, the program state of an enable fuse is blocked, and drawing down of the redundancy determining signal to the GND by the enable fuse is prevented. By separating the enable fuse, the program state of the corresponding address fuse can be checked. The program state of the enable fuse can be also checked. By structuring in such a manner, a semiconductor memory device can be obtained capable of easily confirming whether or not each fuse is set in a right state.

Though the present invention is described in detail based on preferred embodiments, the present invention should not be limited to the embodiments and can be changed in various manners without departing from the essence of the present invention.

1. A semiconductor memory device provided with a redundancy circuit comprising fuses, wherein the semiconductor memory device has a first roll call test mode and a second roll call test mode, and wherein program information of the fuses is separately read out in the first and second roll call test modes.

2. The semiconductor memory device according to claim 1, wherein the semiconductor memory device further comprises a logic circuit which determines a logic output level by using a test mode signal in the second roll call test mode regardless of program information of an enable fuse included in the fuses.

3. The semiconductor memory device according to claim 2, wherein the logic circuit is a two-input NOR circuit using as inputs the test mode signal and the program information of the enable fuse.

4. The semiconductor memory device according to claim 3, wherein the semiconductor memory device further comprises a transistor whose gate is connected to the output of the two-input NOR circuit, whose drain is connected to a redundancy determining signal, and whose source is connected to a ground potential.

5. The semiconductor memory device according to claim 2, wherein the fuse is a capacitor fuse.

6. The semiconductor memory device according to claim 2, wherein the logic circuit is a two-input NOR circuit using as inputs the test mode signal and a reverse signal of an enabling signal.

7. The semiconductor memory device according to claim 6, wherein the semiconductor memory device comprises the fuse whose one end is connected to a redundancy determining signal, and a transistor whose drain is connected to another end of the fuse, whose source is connected to a ground potential, and whose gate is connected to the output of the two-input NOR circuit.

8. The semiconductor memory device according to claim 7, wherein the fuse is a laser fuse.

9. The semiconductor memory device according to claim 3, wherein the fuse is a capacitor fuse.

10. The semiconductor memory device according to claim 4, wherein the fuse is a capacitor fuse.
